(19) United States
(12) Patent Application Publication
(10) Pub. No.: US 2019/0043782 A1
(43) Pub. Date: Feb. 7, 2019

(54) CONFIGURABLE WICKLESS CAPILLARY-DRIVEN CONSTRAINED VAPOR BUBBLE (CVB) HEAT PIPE STRUCTURES

(71) Applicant: Intel Corporation, Santa Clara, CA (US)

(72) Inventors: Sumita Basu, San Jose, CA (US); Aravind Dasu, Milpitas, CA (US); Mahesh A. Iyer, Fremont, CA (US)

(73) Assignee: Intel Corporation, Santa Clara, CA (US)

(21) Appl. No.: 15/981,081

(22) Filed: May 16, 2018

(51) Int. Cl. H01L 23/427; F28D 15/04; F28D 15/06; H01L 25/065; G06F 17/50; H01L 23/34

(52) U.S. Cl. CPC H01L 23/427; F28D 15/046; F28D 15/06; H01L 25/0655; G06F 2217/02; H01L 23/34; G06F 2217/78; G06F 2217/80; G06F 17/5072

(57) ABSTRACT

An integrated circuit package may include one or more integrated circuit dies and reconfigurable constrained vapor bubble (CVB) heat pipe structures formed on the integrated circuit dies. The reconfigurable CVB heat pipe structures may be adjusted using micro-electro-mechanical systems (MEMS) switches. By turning on a MEMS switch, the corresponding heat pipe structure will exhibit a first heat transfer efficiency. By turning off a MEMS switch, the corresponding heat pipe structure will exhibit a second heat transfer efficiency that is less than the first heat transfer efficiency. The reconfigurable CVB heat pipe structures may be statically programmed and/or dynamically adjusted as hot spot locations within the integrated circuit package migrate over time.

### BACKGROUND

This relates generally to integrated circuit packages, and more particularly, to integrated circuit packages with heat dissipation circuitry.

An integrated circuit package typically includes one or more integrated circuit dies mounted on a substrate. As integrated circuit technology scales towards smaller device dimensions, device performance continues to improve at the expense of increased power consumption, which can generate a substantial amount of heat. If this heat is not properly dissipated, circuitry on the integrated circuit package can overheat and suffer from meltdown and degradation in reliability and performance.

In an effort to help dissipate heat in a high-performance integrated circuit package, conventional wicked heat pipes have been developed to help transfer heat among the different dies on the integrated circuit package. Traditional wicked heat pipes include insertable wicked or micro-grooved structures that serve to transport cooling liquid inside an integrated vapor chamber. Conventional wicked heat pipes, however, face a variety of challenges: they are difficult and costly to manufacture (i.e., inserting wicks into heat pipes is a challenging process); they show poor performance in gravity operations; the wicks can cause thermal resistance inside the pipe itself; they exhibit poor durability (i.e., the wicks can often deform, peel, or crack over time); etc.

It is within this context that the embodiments described herein arise.

### BRIEF DESCRIPTION OF THE DRAWINGS

FIG. 1 is a diagram of an illustrative integrated circuit package that includes adjustable constrained vapor bubble (CVB) heat pipe structures in accordance with an embodiment.

FIG. 2A is a diagram of an illustrative adjustable CVB heat pipe structure in a first state in accordance with an embodiment.

FIG. 2B is a cross-sectional view of the adjustable CVB heat pipe structure shown in FIG. 2A in accordance with an embodiment.

FIG. 2C is a diagram of an illustrative adjustable CVB heat pipe structure in a second state in accordance with an embodiment.

FIG. 3A is a diagram of an illustrative integrated circuit package that includes adjustable CVB heat pipe structures for dissipating local hot spots on an integrated circuit die within the integrated circuit package in accordance with an embodiment.

FIG. 3B is a diagram of an illustrative integrated circuit package that includes adjustable CVB heat pipe structures for dissipating local hot spots among multiple integrated circuit dies within the integrated circuit package in accordance with an embodiment.

FIG. 4A is a top view showing one suitable arrangement of adjustable CVB heat pipe structures on an integrated circuit package in accordance with an embodiment.

FIG. 4B is diagram showing how only some of the adjustable CVB heat pipe structures are activated in accordance with an embodiment.

FIG. 4C is a diagram showing how the adjustable CVB heat pipe structures can be used to dilute the three severe hot spots on the integrated circuit package towards regions of lower temperature in accordance with an embodiment.

FIG. 5 is a diagram of a programmable integrated circuit in accordance with an embodiment.

FIG. 6 is a diagram of a circuit design system that can be used to design integrated circuits in accordance with an embodiment.

FIG. 7 is a diagram of illustrative computer-aided design (CAD) tools that may be used in a circuit design system in accordance with an embodiment.

FIG. 8 is a flow chart of illustrative steps for designing an integrated circuit and statically predicting the location of local hot spots on the integrated circuit in accordance with an embodiment.

FIG. 9 is a flow chart of illustrative steps for dynamically forecasting the location of local hot spots during normal application execution time in accordance with an embodiment.

### DETAILED DESCRIPTION

The present embodiments relate to an integrated circuit package with adjustable (reconfigurable) wickless heat pipes such as wickless constrained vapor bubble (CVB) heat pipe structures. The wickless CVB heat pipe structures may be programmed using a micro-electro-mechanical systems (MEMS) switch. When the MEMS switch is disabled, the wickless CVB heat pipe structures may exhibit a first heat transfer efficiency. When the MEMS switch is enabled, the wickless CVB heat pipe structures may exhibit a second heat transfer efficiency that is greater than the first heat transfer efficiency. The wickless CVB heat pipe structures can be arranged and selectively enabled to help dissipate local hot spots within the integrated circuit package. A hot spot or local hot spot may be defined as an area on an integrated circuit device that generates substantially more heat than its surrounding area (e.g., a given region that generates at least 20% more heat, at least 30% more heat, at least 50% more heat, or at least 100% more heat than surrounding regions).

It will be recognized by one skilled in the art, that the present exemplary embodiments may be practiced without some or all of these specific details. In other instances, well-known operations have not been described in detail in order not to unnecessarily obscure the present embodiments.

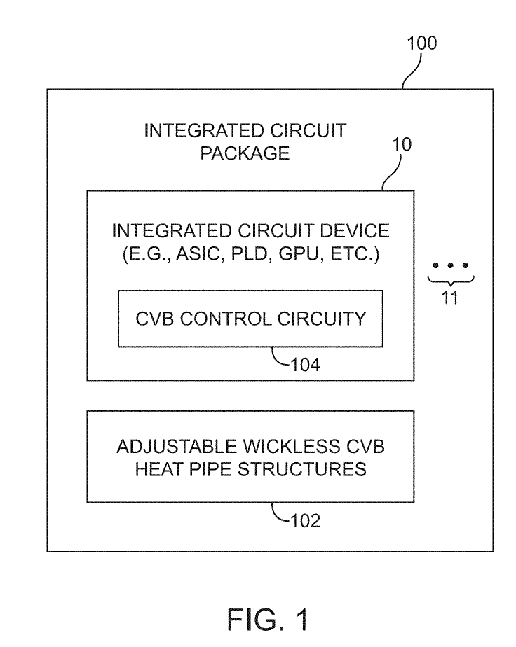

FIG. 1 is a diagram of an integrated circuit package such as integrated circuit package 100. Package 100 may include at least one integrated circuit device 10. Device 10 may, for example, may be a central processing unit (CPU), a graphics processing unit (GPU), an application-specific integrated circuit (ASIC), a programmable logic device (PLD), or other types of processor or logic device. Package 100 may optionally include additional integrated circuit dies, which may include transceivers, memory, networking adapters, and/or other auxiliary components (as indicated by ellipsis 11).

As shown in FIG. 1, integrated circuit package 100 may further include adjustable wickless heat dissipation structures such as adjustable wickless constrained vapor bubble (CVB) heat pipe structures 102 configured to help dissipate heat at one or more areas of high heat concentration (sometimes referred to as “local hot spots”) within integrated circuit package 100. Heat pipe structures 102 may be dynamically reconfigured or reprogrammed to provide the desired heat dissipation capability. In particular, heat pipe structures 102 may controlled using CVB control circuitry 104 formed within main device 10. This is merely illustrative. If desired, heat pipe structures 102 may be controlled any component on package 100 or external to package 100.

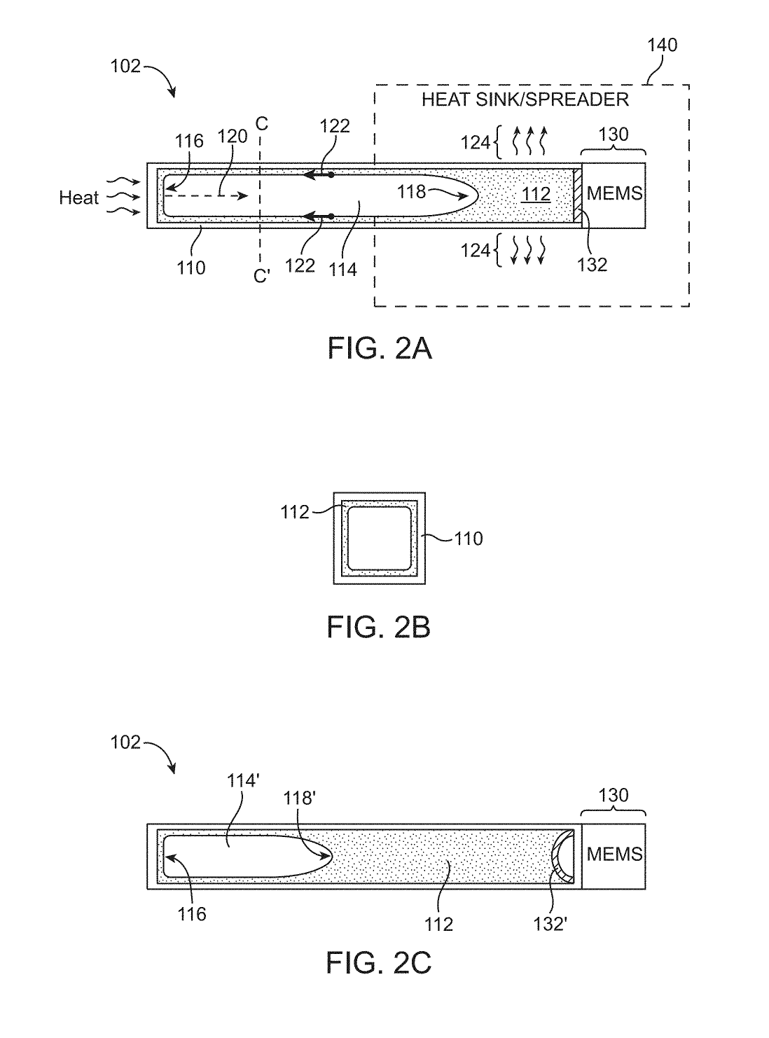

Details of an adjustable wickless CVB heat pipe structure 102 are discussed in connection with FIG. 2A. Heat pipe 102 includes a solid outer housing structure 110 and wetting fluid 112 dispensed within housing 110. Configured in this way, outer housing 110 provides the shape and plumbing for fluid 112 while fluid 112 transport energy/heat via an evaporation and condensation cycle. Housing 110 may be formed from quartz, copper, aluminum, or other types of metal (as examples), but may in general be formed using any suitable type of heat-conducting material. Fluid 112 may be liquid alkane, liquid pentane, methanol, liquid helium, liquid hydrogen, liquid neon, liquid nitrogen, freon, liquid ammonia, liquid cesium, acetone, or even water (as examples), but may in general be any suitable type of liquid that is compatible with the housing material and preferably of low specific heat. The list above is by no means exhaustive of the type of fluid that can be used in CVB heat pipe structures.

As shown in FIG. 2A, outer structure 110 may be partially filled with fluid 112. Fluid 112 may form a pool at one end of heat pipe 102 (e.g., the right end of pipe 102 in the example of FIG. 2A) and can flow towards the other (left) end of pipe 102 via a capillary action, as indicated by arrows 122. A cross-sectional view of heat pipe 102 cut along line C-C′ is shown in FIG. 2B. As shown in FIG. 2B, a combination of surface tension and adsorption causes a thin coating of fluid 112 to form along the inner surface of housing 110 at equilibrium in the absence of any heat applied to pipe 102. In this example in which housing 110 is a rectangular prism having a rectangular cross section, fluid 112 will climb along the four corners due to capillary effect or wicking. Since the corners of housing 110 transport fluid 112 from one end of pipe 102 to another, no wicking structure is needed. Heat pipe 102 of this type is therefore sometimes referred to as a wickless capillary-driven CVB heat pipe structure. The use of capillary-driven heat pipe structures makes for a more robust heat dissipation solution without the challenges inherent to conventional wicked heat pipes.

The portion inside housing 110 that is not occupied by fluid 112 forms a self-contained vapor bubble such as constrained vapor bubble 114. The size of bubble 114 may be defined by the distance between a heated meniscus 116 lining the heated edge of pipe 102 and a bulk meniscus 118 near the bulk portion of fluid 112. In the example of FIG. 2A, the heat applied at the left end of pipe 102 vaporizes the fluid near meniscus 116, which increases the vapor pressure in that region and forces the vaporized fluid to move in direction 120 towards the cooler end where it condenses. The heat is dissipated at the bulk portion of fluid 112, as indicated by arrows 124. Additional heat sink or heat spreading structures 140 (e.g., other air or liquid cooling mechanisms) may be formed at the bulk portion of fluid 112 to enhance heat dispersion. The curvature of the liquid-vapor interface at the corner changes and results in a capillary pressure gradient that pushes the liquid in direction 122, forming a continuous supply of fresh liquid at the heated end. The heat flux enhancement achieved by heat pipe 102 can be quite large even though the temperature gradient may be small.

Still referring to FIG. 2A, adjustable CVB heat pipe 102 may further include a switch such as a micro-electro-mechanical systems (MEMS) switch 130. Switch 130 may include a flexible filament member 132 that is directly coupled to the bulk portion of fluid 112. Switch 130 may, for example, be a piezoelectric device that bends filament 132 when an electric current is passed through switch 130 and allows filament 132 to revert back to its unflexed state when no electric current is applied. This is merely illustrative. In general, switch 130 may be any piston-based device, plunging device, mechanical valve, or other suitable switchable component for displacing fluid 112 within outer housing 110.

FIG. 2C is a diagram showing adjustable heat pipe 102 when switch 130 has been activated. When switch 130 is turned on, the filament is placed in a flexed state 132′, which reduces the volume of the internal cavity within housing 110 and pushes the bulk of fluid 112 towards the heated end. As a result, bubble 114′ becomes smaller (i.e., the distance between heated meniscus 116 and bulk meniscus 118′ is substantially reduced). As an example, engaging switch 130 might reduce the length of the vapor bubble by half, which can increase the power dissipation capability of heat pipe 102 by 50% or more. In general, activating switch 130 might reduce the size of the vapor bubble by at least 25%, at least 50%, at least 75%, etc. Reducing the size of the vapor bubble will help prevent dry out and increases the efficiency of heat removal by more than 30%, more than 60%, or more than 100%. Configured in this way, CVB heat pipe structures 102 with dynamically controllable heat transfer efficacy are sometimes referred to as adjustable CVB heat pipe structures, (re)configurable CVB heat pipe structures, (re)programmable CVB heat pipe structures, etc.

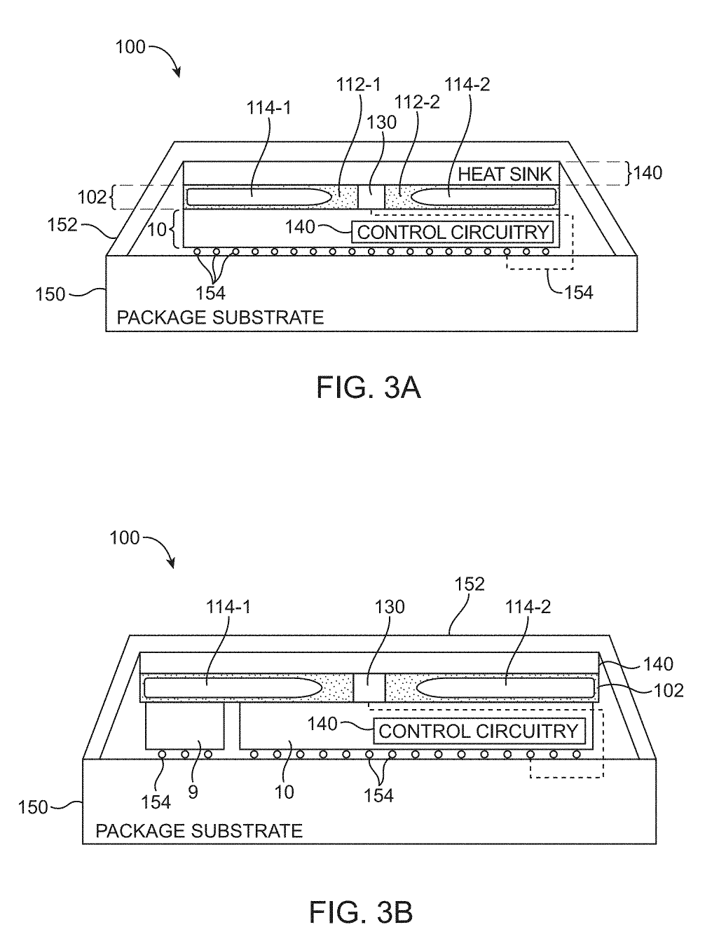

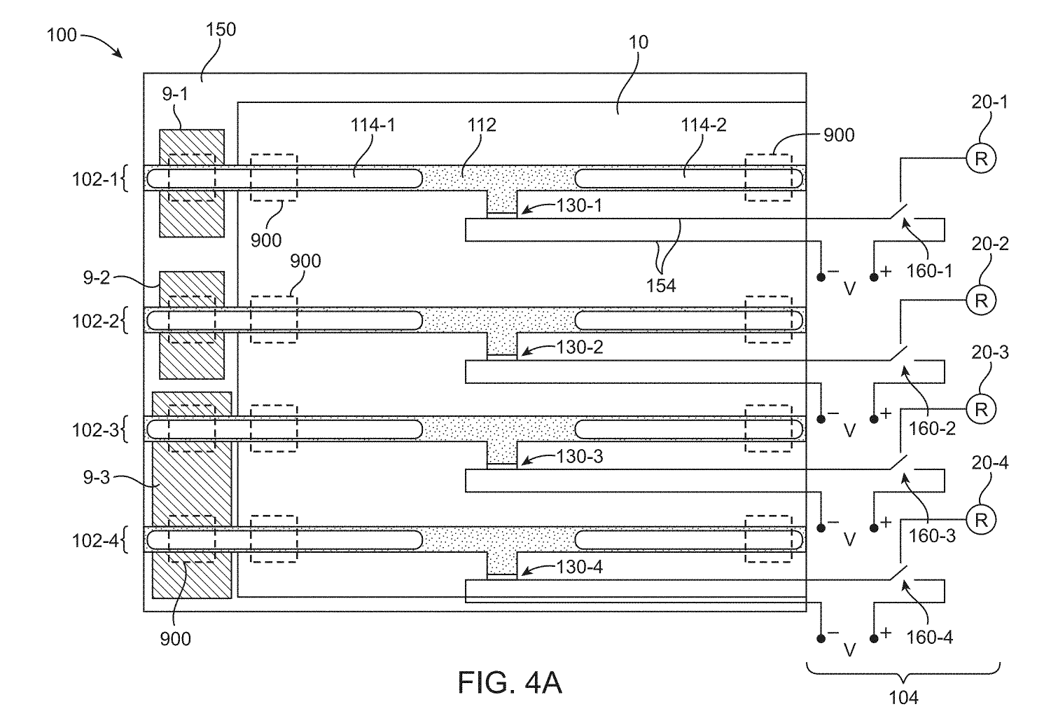

FIG. 3A is a cross-sectional side view of integrated circuit package 100 that includes adjustable CVB heat pipe structures 102. As shown in FIG. 3A, package 100 may include a package substrate 150 with a top surface and a bottom surface and die 10 that is mounted on the top surface of substrate 150 via solder bumps 154 (e.g., controlled collapse chip connection or “C4” bumps). Heat pipe structures 102 may be mounted directly on top of die 10. An additional heat sink 140 or other heating spreading structures may be optionally coupled to heat pipe structures 102. An outer casing such as lid 152 may be formed over heat sink 140 to enclose and protect package 100.

In the example of FIG. 3A, heat pipe structures 102 may include a first constrained vapor bubble 114-1 formed over the left portion of die 10 and a second constrained vapor bubble 114-2 formed over the right portion of die 10. The size of bubbles 114-1 and 114-2 may be adjusted using one or more switches 130, which are configured using control circuitry 104 on die 10 (as indicated schematically by control path 154). In one suitable arrangement, the sizes of bubbles 114-1 and 114-2 may be adjusted in parallel (i.e., activating switch 130 would adjust the size of both bubbles 114-1 and 114-2 simultaneously). In another suitable arrangement, the sizes of bubbles 114-1 and 114-2 may be independently adjusted (i.e., a first MEMS switch is used to adjust the size of bubble 114-1, whereas a second MEMS switch is used to separately adjust the size of bubble 114-2).

Typically, heat generated at the edges or corners of an integrated circuit die tends to be trapped or concentrated in that region since edge/corners portions do not readily disperse heat. Heat pipe structures 102 may be configured to transfer any local hot spots from the edge/peripheral portions of die 10 towards the center or bulk portion of die 10, which offers more volume for lateral dispersion of heat. Configured in this way, heat pipe structures 102 may be selectively activated to transfer heat from the peripheral portions of die 10 to the bulk portion of die 10.

In another suitable embodiment, integrated circuit package 100 may be a multichip package that includes more than one integrated circuit die (see, e.g., FIG. 3B). As shown in FIG. 3B, multichip package 100 may include package substrate 150, die 10 mounted on top of substrate 150, and an additional die 9 mounted on top of substrate 150 laterally beside die 10. Devices 9 and 10 may be electrically coupled to package substrate 150 via solder bumps 154 (e.g., C4 bumps). Heat pipe structures 102 may be mounted directly on top of dies 9 and 10. An additional heat sink 140 or other heating spreading structures may be optionally coupled to heat pipe structures 102. Lid 152 may be formed over heat sink 140 to enclose and protect multichip package 100.

In the example of FIG. 3B, die 9 is much smaller than die 10. Because die 9 is much smaller in size (i.e., much smaller in volume), any heat generated locally at die 9 may be concentrated or trapped within die 9. Heat pipe structures 102 may straddle both die 9 and die 10. In general, heat pipe structures 102 may be extended over any number of components within package 100 and can span the entire width or even the entire area of package 100. Configured in this way, heat pipe structures 102 may bridge any thermal gap between adjacent dies by transferring any potential hot spots on die 9 into the bulk region of die 10. In other words, adjustable CVB heat pipe structures 102 can be configured to simultaneously dump heat from the smaller die 9 to the core region of the larger die 10 while transferring heat from the edges of the larger die 10 to its central bulk region.

Similar to the embodiment of FIG. 3A, the sizes of bubbles 114-1 and 114-2 in FIG. 3B may be adjusted in parallel or may be independently adjusted. Multichip package 100 of FIG. 3B showing only two integrated circuit devices is merely illustrative and does not serve to limit the scope of the present embodiments. In general, multichip package 100 may include more than two integrated circuit devices that are laterally mounted and/or vertically stacked with respect to one another and may include any number of reconfigurable heat pipe structures 102 formed over any group of integrated circuit devices within package 100 to help dilute heat that would otherwise be locally concentrated.

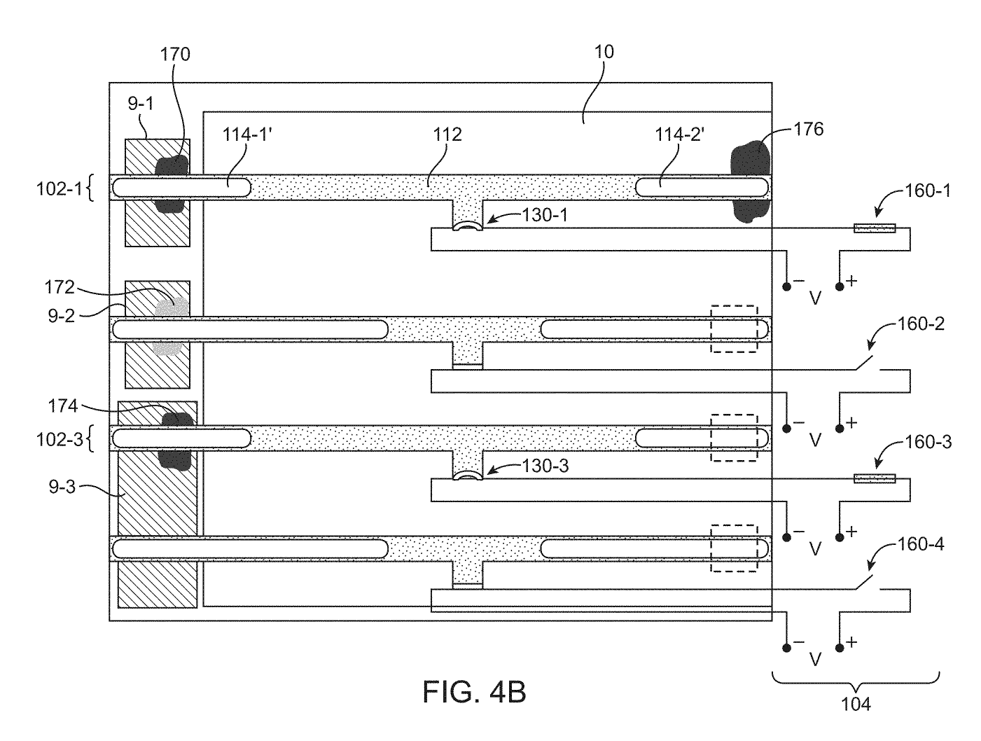

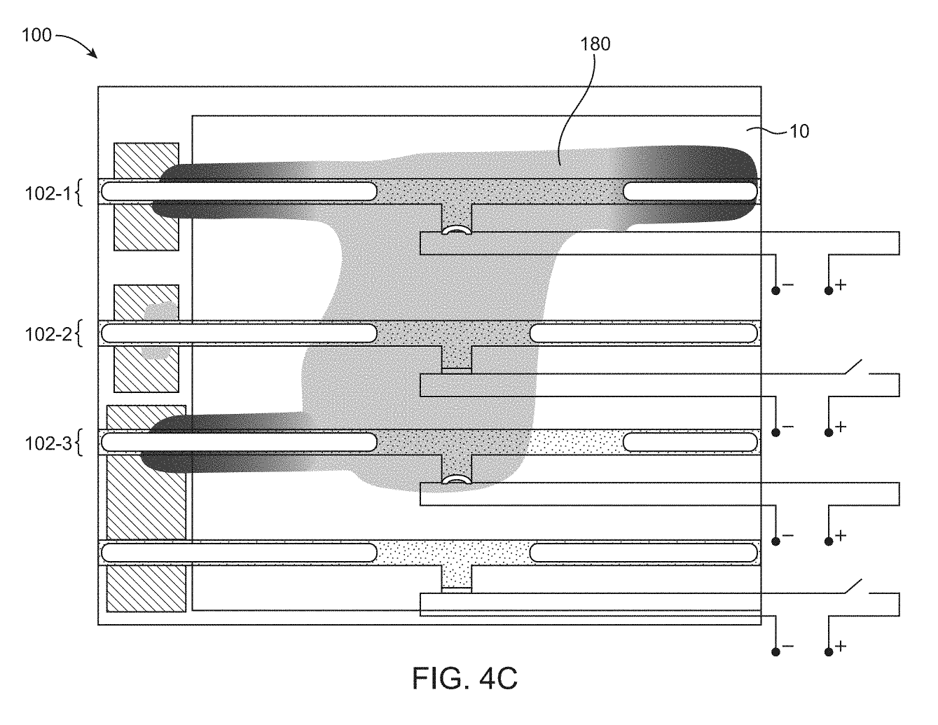

FIG. 4A is a top view showing one suitable arrangement of adjustable CVB heat pipe structures 102 on integrated circuit package 100. As shown in FIG. 4A, integrated circuit package 100 may include a main die 10 and multiple smaller auxiliary (daughter) dies 9-1, 9-2, and 9-3. A first adjustable CVB heat pipe structure 102-1 may be formed over die 10 and die 9-1. A second adjustable CVB heat pipe structure 102-2 may be formed over die 10 and die 9-2. A third adjustable CVB heat pipe structure 102-3 may be formed over die 10 and a first portion of die 9-3, whereas a fourth adjustable CVB heat pipe structure 102-4 may be formed over die 10 and a second portion of die 9-3.

First heat pipe structure 102-1 may be adjusted by first switch 130-1 (e.g., a piezoelectrically-driven switch). First switch 130-1 may be activated by turning on switch 160-1 to apply a voltage V across switch 130-1. Switch 160-1 may be controlled by a corresponding memory element 20-1. The bias voltage V, switch 160-1, and memory element 20-1 may all be considered part of the CVB control circuitry 104 (see, e.g., FIGS. 1 and 3B) that is formed on main die 10. Control circuitry 104 may be coupled to switch 130-1 via control path 154, as shown schematically in FIG. 4A.

Memory element 20-1 may be a volatile memory element (e.g., static random-access memory, configuration random-access memory, dynamic random-access memory, etc.) or a nonvolatile memory element (e.g., read-only memory, erasable programmable read-only memory, electrically erasable programmable read-only memory, flash memory, non-volatile random-access memory, etc.). When memory element 20-1 stores a logic “0”, switch 160-1 is turned off, so the filament in switch 130-1 will be in its neutral unstressed state. When memory element 20-1 stores a logic “1”, switch 160-1 is turned on, which causes the filament in switch 130-1 to flex to a stressed state. When the filament in switch 130-1 is flexed or bent, the size of bubbles 114-1 and 114-2 will be reduced, which substantially increases the heat transfer capability of heat pipe structure 102-1.

Similarly, heat pipe structures 102-2, 102-3, and 102-4 may be respectively adjusted by switches 130-2, 130-3, and 130-4. Switches 130-2, 130-3, and 130-4 may be respectively activated using switches 160-2, 160-3, and 160-4, which are respectively controlled by memory elements 20-2, 20-3, and 20-4. Heat pipe structures 102-2, 102-3, and 102-4 may be controlled using these switches and memory elements in substantially the same way as heat pipe structure 102-1 as described above and need not be repeated in detail. Switches 160-1, 160-2, 160-3, and 160-4 and memory elements 20-1, 20-2, 20-3, and 20-4 may all be considered as part of control circuitry 104 residing on main die 10.

FIG. 4A shows all the adjustable CVB heat pipe structures in the deactivated state. FIG. 4B is diagram showing how some of the adjustable CVB heat pipe structures are activated to help dissipate local hot spots. In the example of FIG. 4B, there may be a first severe hot spot 170 at die 9-1, a second severe hot spot 176 at the right edge of die 10, a third severe hot spot 174 at die 9-3, and a moderate hot spot 172 at die 9-2. The amount of heat at each of the hot spots may be represented by the darkness of each shaded region, where a darker region indicates a greater (or more severe) heat output while a lighter region indicates less severe (or more moderate) heat output.

Since severe hot spot regions 170 and 176 overlap with heat pipe structure 102-1, switch 160-1 may be turned on to activate switch 130-1, thereby reducing the size of bubbles 114-1 and 114-2. Similarly, since severe hot spot region 174 overlap with heat pipe structure 102-3, switch 160-3 may be turned on to activate switch 130-3, which also reduces the size of the vapor constrained bubbles within heat pipe structure 102-3.

FIG. 4C is a diagram showing the final dilution of heat for the three severe hot spots across integrated circuit package 100 towards regions of lower temperature in accordance with an embodiment. As shown by the heat dilution profile 180, activated heat pipe structures 102-1 and 102-3 transfer the heat from the three severe hot spots towards regions of lower temperature (i.e., towards the center bulk region of larger die 10).

In this example, note that heat pipe structure 102-2 is kept deactivated since hot spot 172 was only moderate to begin with. Keeping heat pipe structure 102-2 disengaged maximizes the use of the of the lower temperature region of die 10 to sink heat only from the severe hot spots since heat from even modest or moderate temperature regions would have competed for the valuable low-temperature bulk region at die 10, which could reduce the efficacy of the overall heat management process. In other words, the heat management process not only has to determine the location of the hot spots but also consider the severity of each hot spot region to selectively decide how to provide the optimal heat dilution solution.

The example shown in FIGS. 4A-4C in which there are four separate heat pipe structures extending across the width of package 100 is merely illustrative. If desired, there may be any number of adjustable CVB heat pipe structures formed on package 100; the heat pipe structures may be formed in a grid-like configuration; one or more heat pipe structures may be routed in a L-shaped configuration; one or more heat pipe structures may be arranged in a “+” shaped configuration; one or more heat pipe structures may be routed in a serpentine configuration; etc. These different configurations may share fluid between different CVB heat pipe structures and have varied MEMS switching mechanisms to control and direct appropriate transportation of the shared fluid towards heated areas of the integrated circuit package.

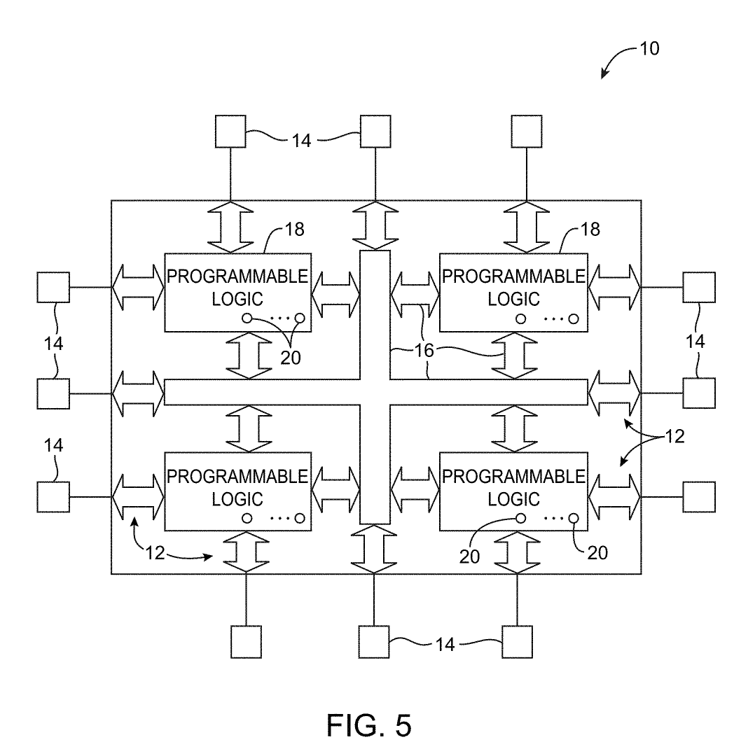

As illustrated by the example of FIGS. 4A-4C, adjustment of each CVB heat pipe structure may depend on the location of local hot spots within package 100. In one suitable embodiment, die 10 may be a programmable integrated circuit (e.g., a programmable logic device), and memory elements 20 may be configuration random-access memory cells on programmable device 10. An illustrative programmable integrated circuit 10 is shown in FIG. 5. As shown in FIG. 5, programmable integrated circuit 10 may have input-output circuitry 12 for driving signals outside of device 10 and for receiving signals from other devices via input-output pins 14. Interconnection resources 16 such as global and local vertical and horizontal conductive lines and buses may be used to route signals on device 10. Interconnection resources 16 include fixed interconnects (conductive lines) and programmable interconnects (i.e., programmable connections between respective fixed interconnects). Programmable logic 18 may include combinational and sequential logic circuitry. The programmable logic 18 may be configured to perform a custom logic function.

Programmable integrated circuit 10 contains memory elements 20 that can be loaded with configuration data (also called programming data) using pins 14 and input-output circuitry 12. Once loaded, the memory elements 20 may each provide a corresponding static control output signal that controls the state of an associated logic component in programmable logic 18. Typically, the memory element output signals are used to control the gates of metal-oxide-semiconductor (MOS) transistors. Some of the transistors may be p-channel metal-oxide-semiconductor (PMOS) transistors. Many of these transistors may be n-channel metal-oxide-semiconductor (NMOS) pass transistors in programmable components such as multiplexers. When a memory element output is high, an NMOS pass transistor controlled by that memory element will be turned on to pass logic signals from its input to its output. When the memory element output is low, the pass transistor is turned off and does not pass logic signals.

A typical memory element 20 is formed from a number of transistors configured to form cross-coupled inverters. Other arrangements (e.g., cells with more distributed inverter-like circuits) may also be used. With one suitable approach, complementary metal-oxide-semiconductor (CMOS) integrated circuit technology is used to form the memory elements 20, so CMOS-based memory element implementations are described herein as an example. In the context of programmable integrated circuits, the memory elements store configuration data and are therefore sometimes referred to as configuration random-access memory (CRAM) cells.

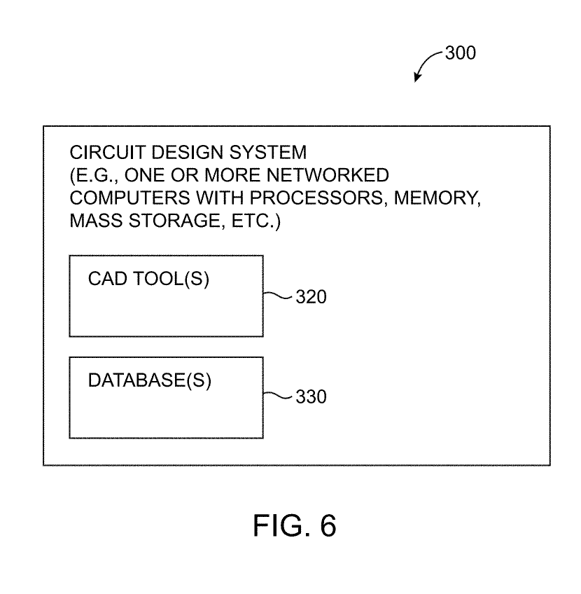

An illustrative circuit design system 300 that can be used to design programmable device 10 is shown in FIG. 6. Circuit design system 300 may be implemented on integrated circuit design computing equipment. For example, system 300 may be based on one or more processors such as personal computers, workstations, etc. The processor(s) may be linked using a network (e.g., a local or wide area network). Memory in these computers or external memory and storage devices such as internal and/or external hard disks may be used to store instructions and data.

Software-based components such as computer-aided design tools 320 and databases 330 reside on system 300. During operation, executable software such as the software of computer aided design tools 320 runs on the processor(s) of system 300. Databases 330 are used to store data for the operation of system 300. In general, software and data may be stored on non-transitory computer readable storage media (e.g., tangible computer readable storage media). The software code may sometimes be referred to as software, data, program instructions, instructions, scripts, or code. The non-transitory computer readable storage media may include computer memory chips such as read-only memory (ROM), non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, floppy diskettes, tapes, or any other suitable memory or storage device(s).

Software stored on the non-transitory computer readable storage media may be executed on system 300. When the software of system 300 is installed, the storage of system 300 has instructions and data that cause the computing equipment in system 300 to execute various methods or processes. When performing these processes, the computing equipment is configured to implement the functions of circuit design system 300.

Computer aided design (CAD) tools 320, some or all of which are sometimes referred to collectively as a CAD tool, a circuit design tool, or an electronic design automation (EDA) tool, may be provided by a single vendor or by multiple vendors. Tools 320 may be provided as one or more suites of tools (e.g., a compiler suite for performing tasks associated with implementing a circuit design in a programmable logic device) and/or as one or more separate software components (tools). Database(s) 330 may include one or more databases that are accessed only by a particular tool or tools and may include one or more shared databases. Shared databases may be accessed by multiple tools. For example, a first tool may store data for a second tool in a shared database. The second tool may access the shared database to retrieve the data stored by the first tool. This allows one tool to pass information to another tool. Tools may also pass information between each other without storing information in a shared database if desired.

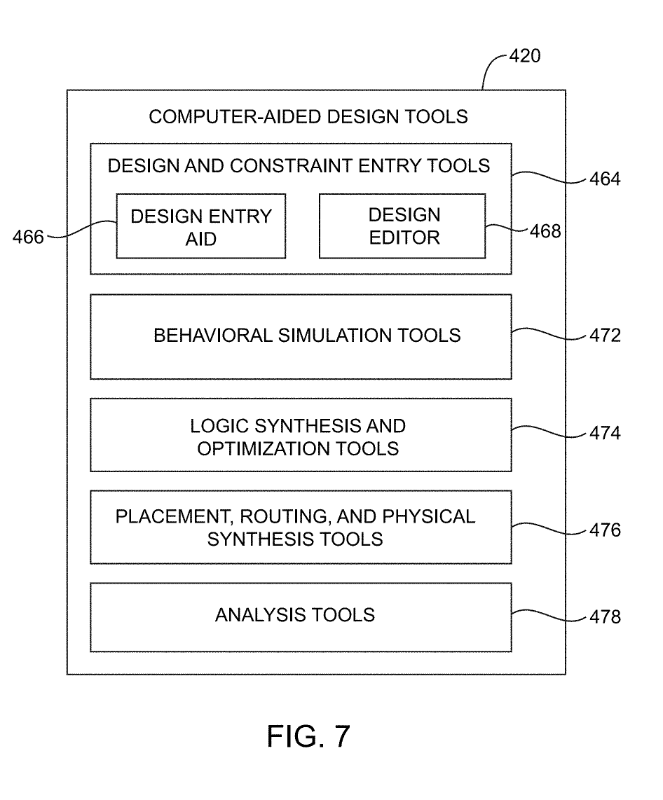

Illustrative computer aided design tools 420 that may be used in a circuit design system such as circuit design system 300 of FIG. 6 are shown in FIG. 7.

The design process may start with the formulation of functional specifications of the integrated circuit design (e.g., a functional or behavioral description of the integrated circuit design). A circuit designer may specify the functional operation of a desired circuit design using design and constraint entry tools 464. Design and constraint entry tools 464 may include tools such as design and constraint entry aid 466 and design editor 468. Design and constraint entry aids such as aid 466 may be used to help a circuit designer locate a desired design from a library of existing circuit designs and may provide computer-aided assistance to the circuit designer for entering (specifying) the desired circuit design.

As an example, design and constraint entry aid 466 may be used to present screens of options for a user. The user may click on on-screen options to select whether the circuit being designed should have certain features. Design editor 468 may be used to enter a design (e.g., by entering lines of hardware description language code), may be used to edit a design obtained from a library (e.g., using a design and constraint entry aid), or may assist a user in selecting and editing appropriate prepackaged code/designs.

Design and constraint entry tools 464 may be used to allow a circuit designer to provide a desired circuit design using any suitable format. For example, design and constraint entry tools 464 may include tools that allow the circuit designer to enter a circuit design using truth tables. Truth tables may be specified using text files or timing diagrams and may be imported from a library. Truth table circuit design and constraint entry may be used for a portion of a large circuit or for an entire circuit.

As another example, design and constraint entry tools 464 may include a schematic capture tool. A schematic capture tool may allow the circuit designer to visually construct integrated circuit designs from constituent parts such as logic gates and groups of logic gates. Libraries of preexisting integrated circuit designs may be used to allow a desired portion of a design to be imported with the schematic capture tools.

If desired, design and constraint entry tools 464 may allow the circuit designer to provide a circuit design software application code to the circuit design system 300 using a hardware description language such as Verilog hardware description language (Verilog HDL), Very High Speed Integrated Circuit Hardware Description Language (VHDL), SystemVerilog, or a higher-level circuit description language such as OpenCL, SystemC, C/C++, just to name a few. The designer of the integrated circuit design can enter the circuit design by writing the application code with editor 468. Blocks of code may be imported from user-maintained or commercial libraries if desired.

After the design has been entered using design and constraint entry tools 464, behavioral simulation tools 472 may be used to simulate the functionality of the circuit design. If the functionality of the design is incomplete or incorrect, the circuit designer can make changes to the circuit design using design and constraint entry tools 464. The functional operation of the new circuit design may be verified using behavioral simulation tools 472 before synthesis operations have been performed using tools 474. Simulation tools such as behavioral simulation tools 472 may also be used at other stages in the design flow if desired (e.g., after logic synthesis). The output of the behavioral simulation tools 472 may be provided to the circuit designer in any suitable format (e.g., truth tables, timing diagrams, etc.).

Once the functional operation of the circuit design has been determined to be satisfactory, logic synthesis and optimization tools 474 may generate a gate-level netlist of the circuit design, for example using gates from a particular library pertaining to a targeted process supported by a foundry, which has been selected to produce the integrated circuit. Alternatively, logic synthesis and optimization tools 474 may generate a gate-level netlist of the circuit design using gates of a targeted programmable logic device (i.e., in the logic and interconnect resources of a particular programmable logic device product or product family).

Logic synthesis and optimization tools 474 may optimize the design by making appropriate selections of hardware to implement different logic functions in the circuit design based on the circuit design data and constraint data entered by the logic designer using tools 464. As an example, logic synthesis and optimization tools 474 may perform multi-level logic optimization and technology mapping based on the length of a combinational path between registers in the circuit design and corresponding timing constraints that were entered by the logic designer using tools 464.

After logic synthesis and optimization using tools 474, the circuit design system may use tools such as placement, routing, and physical synthesis tools 476 to perform physical design steps (layout synthesis operations). Tools 476 can be used to determine where to place each gate of the gate-level netlist produced by tools 474. For example, if two counters interact with each other, tools 476 may locate these counters in adjacent regions to reduce interconnect delays or to satisfy timing requirements specifying the maximum permitted interconnect delay. Tools 476 create orderly and efficient implementations of circuit designs for any targeted integrated circuit (e.g., for a given programmable integrated circuit such as a field-programmable gate array (FPGA)).

Tools such as tools 474 and 476 may be part of a compiler suite (e.g., part of a suite of compiler tools provided by a programmable logic device vendor). In certain embodiments, tools such as tools 474, 476, and 478 may also include timing analysis tools such as timing estimators. This allows tools 474 and 476 to satisfy performance requirements (e.g., timing requirements) before actually producing the integrated circuit.

After an implementation of the desired circuit design has been generated using tools 476, the implementation of the design may be analyzed and tested using analysis tools 478. For example, analysis tools 478 may include timing analysis tools, power analysis tools, or formal verification tools, just to name few.

After satisfactory optimization operations have been completed using tools 420 and depending on the targeted integrated circuit technology, tools 420 may produce a mask-level layout description of the integrated circuit or configuration data for programming the programmable logic device.

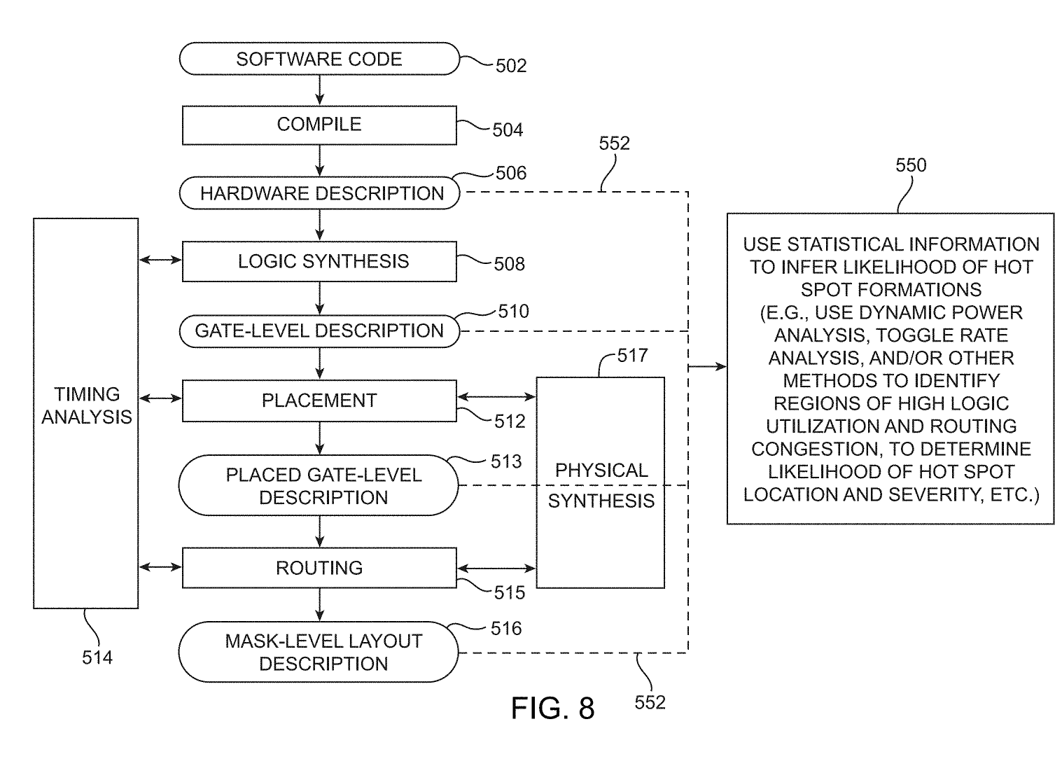

Illustrative operations involved in using tools 420 of FIG. 7 to produce the mask-level layout description of the integrated circuit are shown in FIG. 8. A circuit designer may first provide a design specification. The design specification may, in general, be a behavioral description provided in the form of a software application source code 502 (e.g., C code, C++ code, SystemC code, OpenCL code, etc.).

At step 504, tools 420 may compile source code 502 via a process sometimes referred to as behavioral synthesis or algorithmic synthesis to convert code 502 into a hardware description 506. Hardware description 506 may (as an example) be a register transfer level (RTL) description. The RTL description may have any form of describing circuit functions at the register transfer level. For example, the RTL description may be expressed using a hardware description language such as the Verilog hardware description language (Verilog HDL or Verilog), the SystemVerilog hardware description language (SystemVerilog HDL or SystemVerilog), or the Very High Speed Integrated Circuit Hardware Description Language (VHDL).

In general, code 502 may include untimed or partially timed functional code (i.e., the application code does not describe cycle-by-cycle hardware behavior), whereas the hardware description 506 may include a fully timed design description that details the cycle-by-cycle behavior of the circuit at the register transfer level.

Code 502 and/or hardware description 506 may also include target criteria such as area use, power consumption, delay minimization, clock frequency optimization, or any combination thereof. The optimization and target criteria may be collectively referred to as constraints.

Those constraints can be provided for individual data paths, portions of individual data paths, portions of a design, or for the entire design. For example, the constraints may be provided with code 502, description 506, in a constraint file, or through user input (e.g., using the design and constraint entry tools 464 of FIG. 7), to name a few.

During step 508, logic synthesis operations may generate gate-level description 510 from hardware description 506 using logic synthesis and optimization tools 474 (FIG. 7). The output of logic synthesis 508 is a gate-level description 510 of the design.

During step 512, placement operations using placement tools 476 of FIG. 7 may place the different gates in gate-level description 510 in a preferred location on the targeted integrated circuit to meet given target placement criteria (e.g., to minimize area and maximize routing efficiency or minimize path delay and maximize clock frequency or minimize overlap between logic elements, or any combination thereof). The output of placement 512 is a placed gate-level description 513, which satisfies the legal placement constraints of the underlying target device.

During step 515, routing operations using for example routing tools 476 of FIG. 7 may connect the gates from the placed gate-level description 513. Routing operations may attempt to meet given target routing criteria (e.g., to minimize congestion, minimize path delay and maximize clock frequency, satisfy minimum delay requirements, or any combination thereof). The output of routing 515 is a mask-level layout description 516 (sometimes referred to as routed gate-level description 516).

While placement and routing are being performed at steps 512 and 515, physical synthesis operations 517 may be concurrently performed to further modify and optimize the circuit design (e.g., using physical synthesis tools 476 of FIG. 7).

During the design and compilation phase, CAD tools 420 (FIG. 7) may use statistical information about the nature of the circuit design and the layout of the circuits gathered throughout the design flow (as indicated by dotted path 552) to infer the likelihood of hot spot formations within die 10 (see step 550). For example, analysis tools 478 of FIG. 7 may be used to perform dynamic power analysis, toggle rate analysis, and/or other processes to help identify regions of high logic utilization and routing congestion, to help determine the likelihood of hot spot location and severity, etc. Performing dynamic power analysis may entail simulating random vectors and measuring the switching activity of various signals in the design, which would reveal the amount of dynamic power consumed by the design during actual operation. Probabilistic simulation can also be used to determine the probabilities of switching for various signals, nodes, and/or inputs or outputs of every cell in the design, which predicts the amount of dynamic power consumption by various signals in the design. Toggle rate analysis might be helpful when a set of designs are programmed onto a programmable device. The exact toggling of signals can be measured during normal execution of the designs on the device, which can then be used to generate heuristics to refine or supplement the dynamic power analysis.

Once design tools 420 knows where severe hot spots are likely to occur on die 10, tools 420 can then modify the final layout description 516 to ensure that only the heat pipe structures directly overlapping with the serve hot spot regions are activated (e.g., by programming the associated CRAM elements 20 to store logic ones).

The example above in which the determination of which heat pipe structures to engage is performed during the design/compilation phase of an integrated circuit is merely illustrative. In another suitable embodiment, which is not exclusive to step 550 above but can optionally be used to supplement step 550, the CVB heat pipe structures may be dynamically adjusted during application runtime. This may be advantageous because hot spots can change location over time due to dynamic thermal migration or shifts in an application design's stress points that can naturally occur.

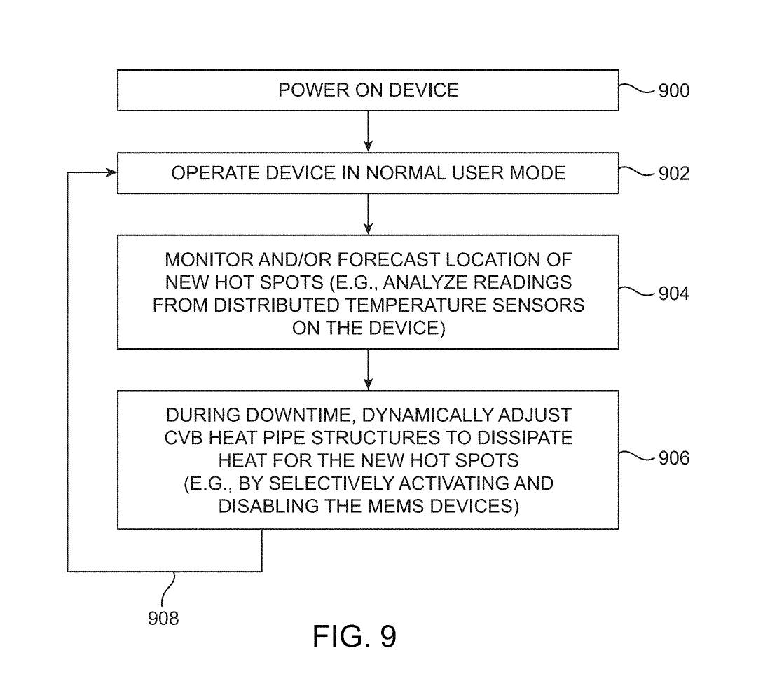

FIG. 9 is a flow chart of illustrative steps for dynamically forecasting the location of new hot spot locations during normal application execution time. At step 900, a user powers on integrated circuit package 100. At step 902, package 100 is placed in normal user mode to run the desired application.

At step 904, package 100 may be configured to monitor and/or forecast the location of new hot spots. For example, package 100 might analyze the readings from distributed temperature sensors such as sensors 900 (see FIG. 4A) embedded within the different integrated circuit dies on package 100. As shown in FIG. 4A, temperature sensors 900 may be placed along the edges or corners of die 10 at least partially under or directly under the distal ends of each adjustable CVB heat pipe structure or at any location on die 10 where severe hot spots might exist in practice. There may also be temperature sensors 900 on each of the smaller dies 9 (e.g., dies 9-1, 9-2, and 9-3). In the example of FIG. 4A, there are actually two temperature sensors 900 on die 9-3 since there are two different adjustable CVB heat pipe structures that can possibly be used to dissipate heat from die 9-3.

In general, there may be any suitable number of temperature sensors 900 distributed across the surface of each die within integrated circuit package 900. Temperature sensors 900 may be thermistor-based temperature sensing circuits, diode-based temperature sensing circuits (e.g., silicon bandgap temperature sensors), and/or other suitable type of integrated circuit temperature sensing components.

Temperature sensors 900 may pass the temperature measurement readings to control circuitry 104 (FIG. 1). During downtime (e.g., when the application is temporarily idle), control circuitry 104 may dynamically adjust the CVB heat pipe structures to dissipate heat for the newly detected hot spots by selectively turning on and/or turning off the corresponding MEMS switches (step 906). This process for dynamically reprogramming the adjustable heat pipe structures may be periodically iterated to ensure that the configuration of the CVB heat pipe structures keep up with the migration of the hot spots (as indicated by path 908).

The ability to embed multiple adjustable CVB heat pipe structures on integrated circuits and the capability to program and reprogram the CVB heat pipe structures using MEMS switches to remove heat from local hot spots allows users to tackle heat generation in a dynamic manner without running into thermal management limitations, thereby providing more flexibility and increased performance for longer periods of time.

The foregoing is merely illustrative of the principles of this invention and various modifications can be made by those skilled in the art. The foregoing embodiments may be implemented individually or in any combination.

What is claimed is:

1. Circuitry, comprising:
an integrated circuit die;
an adjustable constrained vapor bubble (CVB) heat pipe structure coupled to the integrated circuit die; and
a micro-electro-mechanical systems (MEMS) switch configured to adjust the adjustable CVB heat pipe structure.

2. The circuitry of claim 1, wherein the adjustable CVB heat pipe structure is wickless.

3. The circuitry of claim 1, wherein the MEMS switch comprises a piezoelectric switch.

4. The circuitry of claim 1, wherein the adjustable CVB heat pipe structure includes at least a first constrained vapor bubble at a first end and a second constrained vapor bubble at a second end, and wherein the MEMS switch is configured to simultaneously adjust the size of the first and second constrained vapor bubbles.

5. The circuitry of claim 1, wherein the adjustable CVB heat pipe structure includes a first constrained vapor bubble at a first end and a second constrained vapor bubble at a second end, and wherein the size of the first and second constrained vapor bubbles are independently adjustable.

6. The circuitry of claim 1, further comprising:
control circuitry for selectively activating the MEMS switch, wherein the control circuitry comprises a memory element configured to store a logic one to activate the MEMS switch and to store a logic zero to deactivate the MEMS switch.

7. The circuitry of claim 1, wherein the adjustable CVB heat pipe structure spans the entire width of the integrated circuit die. xx

8. The circuitry of claim 1, further comprising:
an additional integrated circuit die that is smaller than the integrated circuit die, wherein the adjustable CVB heat pipe structure extends over both the integrated circuit die and the additional integrated circuit die and is configured to transfer heat from the additional integrated circuit die to a bulk region of the integrated circuit die.

9. The circuitry of claim 1, further comprising:
an additional adjustable constrained vapor bubble (CVB) heat pipe structure coupled to the integrated circuit die; and
an additional micro-electro-mechanical systems (MEMS) switch configured to adjust the additional adjustable CVB heat pipe structure.

10. The circuitry of claim 1, wherein the integrated circuit die comprises a temperature sensing circuit formed at least partially under the adjustable CVB heat pipe structure.

11. A method of operating circuitry that includes an integrated circuit die and a configurable constrained vapor bubble (CVB) heat pipe structure, the method comprising:
operating the integrated circuit die, wherein the integrated circuit die exhibits a hot spot; and
activating the configurable CVB heat pipe structure to transfer heat from the hot spot to a bulk region of the integrated circuit die.

12. The method of claim 11, further comprising:
turning on a micro-electro-mechanical system (MEMS) switch to activate the configurable CVB heat pipe structure.

13. The method of claim 12, wherein the configurable CVB heat pipe structure includes at least a first constrained vapor bubble at a first end and a second constrained vapor bubble at a second end, and wherein turning on the MEMS switch simultaneously adjusts the size of the first and second constrained vapor bubbles.

14. The method of claim 12, wherein turning on the MEMS switch comprises loading a logic one into an associated memory element on the integrated circuit die.

15. The method of claim 11, further comprising:
using at least one temperature sensor on the integrated circuit die to determine whether or not to activate the configurable CVB heat pipe structure.

16. The method of claim 15, further comprising:
dynamically deactivating the configurable CVB heat pipe structure based on temperature measurements obtained from the at least one temperature sensor.

17. A method for using integrated circuit design tools to implement an integrated circuit, the method comprising:
compiling a source code to generate a corresponding hardware description;
generating a circuit layout for the integrated circuit based on the hardware description;
using statistical information associated with the circuit layout to infer the likelihood of hot spot formation on the integrated circuit; and
programming reconfigurable constrained vapor bubble (CVB) heat pipe structures coupled to the integrated circuit based on the inferred likelihood of hot spot formation on the integrated circuit.

18. The method of claim 17, further comprising:
performing dynamic power analysis to infer the likelihood of hot spot formation.

19. The method of claim 17, further comprising:
performing toggle rate analysis to infer the likelihood of hot spot formation.

20. The method of claim 17, further comprising:
identifying regions of high logic utilization and routing congestion on the integrated circuit.

21. The method of claim 17, further comprising:
predicting the physical location and the severity of each hot spot on the integrated circuit.

22. The method of claim 17, further comprising:
programming soft logic on the integrated circuit to monitor signal toggling rates and switching activities on the integrated circuit, wherein the soft logic is configured to adjust the reconfigurable CVB heat pipe structures based on the monitored signal toggling rates and switching activities.
